(19) United States
(12) Patent Application Publication
(10) Pub. No.: US 2024/0079506 A1
(43) Pub. Date: Mar. 7, 2024

(54) SURFACE TREATMENT METHOD FOR FORMING A PASSIVATED CONTACT OF A SOLAR CELL

(71) Applicant: National University of Singapore, Singapore (SG)

(72) Inventors: Pradeep PADHAMNATH, Singapore (SG); Shubham DUTTAGUPTA, Singapore (SG); Nitin NAMPALLI, Singapore (SG)

(21) Appl. No.: 18/284,647

(22) PCT Filed: Mar. 28, 2022
(86) PCT No.: PCT/SG2022/050169

§ 371 Date: Sep. 28, 2023

(30) Foreign Application Priority Data
Mar. 29, 2021 (SG) 10202103200Y

(51) Int. Cl. H01L 31/0216; H01L 31/18

(52) U.S. Cl. CPC H01L 31/02167; H01L 31/1804

(57) ABSTRACT

Surface treatment method for forming a passivated contact of a solar cell A surface treatment method for forming a passivated contact of a solar cell 100 is described. In an embodiment, the solar cell 100 comprises a silicon layer 102 having a textured surface, and the method comprises: (i) etching a portion of the silicon layer 102 using a first etchant to reduce surface protrusions of the textured surface and to provide an intermediate surface of the silicon layer 102; and (ii) etching the intermediate surface of the silicon layer 102 using a second etchant to form a treated surface of the silicon layer 102 having a desired roughness for forming the passivated contact of the solar cell, the second etchant having a slower etching rate on silicon than that of the first etchant.

### CROSS-REFERENCE TO RELATED APPLICATIONS

The present application is a national phase entry under 35 U.S.C. § 371 of International Application No. PCT/SG2022/050169, filed Mar. 28, 2022, published in English, which claims the benefit of the filing date of Singapore Patent Application No. 10202103200Y, filed Mar. 29, 2021, the disclosures of which are incorporated herein by reference.

### TECHNICAL FIELD

The present disclosure relates to a surface treatment method, in particular, a surface treatment method for forming a passivated contact of a solar cell.

### BACKGROUND

The photovoltaic market is currently dominated by wafer based, crystalline silicon (Si) solar cells. Particularly, the passivated emitter rear cell (PERC) technology provides a high efficiency solar cell architecture which accounts for more than 60% of the world market share for solar cell fabricated at present. The PERC architecture generally provides small areas of metal contacts at a rear side of a Si wafer of the solar cell, which aids to reduce recombination losses in the solar cell.

Heralded as an improvement to the PERC technology is the use of passivated contacts, which incorporates thin films within the contact structure that simultaneously suppress recombination and promote charge-carrier selectivity. Among the many candidates for passivated contacts used in the Si photovoltaic industry, passivated contacts formed using doped polysilicon (poly-Si) and ultrathin interfacial oxide layer have been the most commercially successful.

In a typical PERC architecture, an emitter is typically formed by a horizontal tube thermal diffusion process using a liquid dopant source. The horizontal tube thermal diffusion process is inherently a two-sided process where both a front side and a rear side of a Si wafer will be doped. In order to form passivated contacts on the rear side of such solar cells, the doped Si layer at the rear side will have to be etched away. Further, to form passivated contacts with desired contact characteristics, not only the doped Si layer has to be removed, but a desired rear surface morphology has to be achieved. Still further, existing etching and/or surface treatment methods typically involve a mixture of two or more chemicals of high concentrations. For example, this includes a mixture of 5-10 wt % hydrofluoric acid (HF) and 20-40 wt % nitric acid (HNO₃) or a mixture of 10-20 wt % potassium hydroxide (KOH) and 5-10 wt % isopropyl alcohol (IPA). Such etching mixtures of high concentrations typically result in high etch rates (typically in the range of 1 μm/min) which cannot be easily controlled. In addition, these mixtures with high concentrations of chemicals are prone to non-uniformity in etching if there is insufficient mixing of these chemicals during the etching process.

It is therefore desirable to provide a surface treatment method for forming passivated contacts of a solar cell which addresses the problems of the prior art and/or provides a useful alternative.

Furthermore, other desirable features and characteristics will become apparent from the subsequent detailed description and the appended claims, taken in conjunction with the accompanying drawings and this background of the disclosure.

### SUMMARY

Aspects of the present application relate to a surface treatment method for forming a passivated contact of a solar cell.

In accordance with a first aspect, there is provided a surface treatment method for forming a passivated contact of a solar cell, the solar cell comprising a silicon layer having a textured surface, the method comprising: (i) etching a portion of the silicon layer using a first etchant to reduce surface protrusions of the textured surface and to provide an intermediate surface of the silicon layer; and (ii) etching the intermediate surface of the silicon layer using a second etchant to form a treated surface of the silicon layer having a desired roughness for forming the passivated contact of the solar cell, the second etchant having a slower etching rate on silicon than that of the first etchant.

Thus, the described embodiment provides a method for treating or preparing a surface of a Si layer prior to forming a passivated contact of a solar cell. In particular, the method includes a first etching step (i) for etching a portion of the silicon layer using a first etchant to reduce surface protrusions of a textured surface of the Si layer and to provide an intermediate surface; and a second etching step (ii) for etching the intermediate surface using a second etchant to form a treated surface of the silicon layer having a desired roughness for forming the passivated contact of the solar cell, where the second etchant has a slower etching rate on silicon than that of the first etchant. The first etching step therefore serves to smoothen out a surface roughness of the silicon layer (e.g. smoothening tips of Si pyramid microstructures of the silicon layer), while the slower second etching step serves to provide a handle to control a roughness of the treated surface of the silicon layer. Particularly, with a slower second etching step, an etch depth and/or roughness can be increased or decreased depending on a duration of the second etching step, without severely altering a surface morphology of the treated surface. To achieve quality passivated contacts that provide a good solar cell efficiency, a surface morphology of the wafer or layer on which the passivated contacts are formed is critical. Particularly, while planar surfaces result in better open-circuit voltages (V_{OC}), textured or rough surfaces allow for excellent contact formation. The second etching step, which is slower than the first etching step, can be controlled more easily and with higher accuracy to achieve the desired roughness for forming quality passivated contacts in solar cells.

The method may comprise etching the silicon layer anisotropically to form the textured surface of the silicon layer.

The second etchant may be a single component etching solution. In this case, no mixing is required in preparing the single component etchant. This therefore reduces time and costs to prepare the single component etchant for use in the second etching step. Having a single component etchant also means that there is no concentration gradient within the second etchant. This eliminates the need of mixing during the etching step, and provides a more uniform and controlled etching process.

The second etchant may include sodium hypochlorite (NaOCl). NaOCl is generally less expensive than commercially available etching solutions, and this translates to savings for the manufacturing cost. The non-hazardous nature of NaOCl also means that it requires minimal treatment before disposal, thereby further reducing process costs and environmental impacts.

The step (ii) of the method may be performed at a temperature of 30° C. to 85° C. for a duration of 5 minutes to 15 minutes. In some embodiments, the step (ii) of the method may be performed at a temperature of 65° C. to 85° C. for a duration of 10 minutes to 15 minutes, or at a temperature of 70° C. to 80° C. for a duration of 10 minutes to 15 minutes.

A concentration of the NaOCl may be in a range of 10% to 15% by weight.

The desired roughness of the treated surface of the silicon layer may be in a range of 0.2 μm to 0.5 μm.

Where the silicon layer has a front side arranged to receive incident light and a rear side, the silicon layer may be doped on both the front side and the rear side in a process for forming an emitter on the front side of the silicon layer, the step (i) of the method may be adapted to etch away a doped layer of the silicon layer on the rear side for forming the passivated contact on the rear side of the silicon layer. The integration of the first etching step in the existing etching process step (either for inline wet chemical etching tool or batch wet chemical etching tool) translates to time and cost saving for manufacturing such solar cell.

The process may include doping the silicon layer using a boron dopant source, the first etchant may include a mixture of hydrofluoric (HF) and nitric acid (HNO3).

The method may comprise depositing a masking layer on the front side of the silicon layer after the silicon layer is doped and prior to the step (i) of the method to protect a doped layer of the front side of the silicon layer.

The first etchant may include a potassium hydroxide (KOH) solution or a mixture of hydrofluoric (HF) and nitric acid (HNO3).

The first etchant may include the KOH solution, where the concentration of KOH may be in a range of 2% to 20% by weight. In some embodiments, the concentration of KOH may be in a range of 15% to 20% by weight.

Where the first etchant includes a KOH solution, the step (i) of the method may be performed at a temperature of 30° C. to 85° C. for a duration of 15 seconds to 3 minutes. In some embodiments, the step (ii) of the method may be performed at a temperature of 65° C. to 85° C. for a duration of 30 seconds to 2 minutes. In some embodiments, the step (ii) of the method may be performed at a temperature of 60° C. to 80° C. for a duration of 15 seconds to 30 seconds.

The first etchant may include the mixture of HF and HNO3, the concentration of HF may be in a range of 2% to 10% by weight and the concentration of HNO3 may be in a range of 25% to 45% by weight.

Where the first etchant includes a mixture of HF and HNO3, the step (i) of the method may be performed at a temperature of 18° C. to 30° C. for a duration of 30 seconds to 3 minutes. In some embodiments, the step (ii) of the method may be performed at a temperature of 20° C. to 30° C. for a duration of 1 minute to 2 minutes.

The method may be performed using a batch wet chemical tool or an inline wet chemical tool. The method can be performed independent of the tools used and can be easily implemented or integrated in any solar cell fabrication process for forming passivated contacts.

The step (i) and/or the step (ii) of the method may include wet etching steps.

Embodiments therefore provide a method for treating or preparing a surface of a Si layer prior to forming a passivated contact of a solar cell. In particular, the method includes a first etching step (i) for etching a portion of the silicon layer using a first etchant to reduce surface protrusions of a textured surface of the Si layer and to provide an intermediate surface; and a second etching step (ii) for etching the intermediate surface using a second etchant to form a treated surface of the silicon layer having a desired roughness for forming the passivated contact of the solar cell, where the second etchant has a slower etching rate on silicon than that of the first etchant. The first etching step serves to reduce a roughness of the textured surface of the silicon layer, while the slower second etching step serves to provide a handle to control an eventual roughness of the treated surface of the silicon layer. By using the slower second etching step, an etch depth and/or roughness can be controllably increased or decreased depending on a duration of the second etching step, without severely altering a surface morphology of the treated surface. The desired roughness produced by the surface treatment method in turn results in better passivated contact and therefore higher fill factors and efficiency for the solar cell.

Further, in an embodiment where the second etchant is a single component etching solution, no mixing is required in preparing this single component etchant. This therefore reduces time and costs in the preparation of the single component etchant for use in the second etching step. Having a single component etchant also means that there is no concentration gradient within the second etchant. This eliminates the need of mixing during the etching step, and provides a more uniform and controlled etching process. Still further, in an embodiment, sodium hypochlorite (NaOCl) is used as the second etchant. NaOCl is generally less expensive than commercially available etching solutions, and this translates to savings for the manufacturing cost. The non-hazardous nature of NaOCl also means that it requires minimal treatment before disposal, thereby further reducing process costs and environmental impacts. In an embodiment, both the first etching step (i) and the second etching step (ii) involve wet chemical etching processes which can be easily implemented or integrated with the existing wet chemical equipment, so that less upfront capital cost is required to implement these processes. Still further, in an embodiment where a silicon layer of a solar cell has a front side arranged to receive incident light and a rear side, and the silicon layer is doped on both the front side and the rear side in a process for forming an emitter on the front side of the silicon layer, the step (i) of the method can be adapted to etch away a doped layer of the silicon layer on the rear side for forming the passivated contact on the rear side of the silicon layer. The integration of the first etching step in the existing etching process step (either for inline wet chemical etching tool or batch wet chemical etching tool) translates to time and cost saving for manufacturing such solar cell.

### BRIEF DESCRIPTION OF THE DRAWINGS

Embodiments will now be described, by way of example only, with reference to the following drawings, in which:

FIGS. 1A, 1B, 1C and 1D show schematic structures of a solar cell in accordance with embodiments, where FIG. 1A shows a solar cell with a front side p⁺ emitter and rear passivated contacts having a n⁺ poly-Si layer, FIG. 1B shows a solar cell with a front side n⁺ emitter and rear passivated contacts having a p⁺ poly-Si layer, FIG. 1C shows a solar cell with front passivated contacts having a p⁺ poly-Si layer and rear passivated contacts having a n⁺ poly-Si layer and FIG. 1D shows a solar cell with front passivated contacts having a n⁺ poly-Si layer and rear passivated contacts having a p⁺ poly-Si layer;

FIG. 2 is a flowchart showing steps of a method for fabricating the solar cell of FIG. 1A in accordance with an embodiment;

FIG. 3 is a flowchart showing steps of a surface treatment method for forming a passivated contact of a solar cell used in the fabrication method of FIG. 2 in accordance with an embodiment;

FIG. 4 is a flowchart showing steps of a method for forming a passivated contact of the solar cell of FIG. 1A in accordance with an embodiment;

FIGS. 5A, 5B and 5C show three-dimensional (3D) microscopy images of a surface of a Si wafer after a surface treatment process, where FIG. 5A shows a 3D microscopy image of a surface of a Si wafer after being treated by an alkaline solution, FIG. 5B shows a 3D microscopy image of a surface of a Si wafer after being treated by an acidic solution and FIG. 5C shows a 3D microscopy image of a surface of a Si wafer after being processed using the surface treatment method of FIG. 3 in accordance with an embodiment;

FIGS. 6A, 6B and 6C show scanning electron microscopy (SEM) images of the surface of the Si wafer corresponding to FIGS. 5A, 5B and 5C respectively, where FIG. 6A shows a SEM image of the surface of the Si wafer after being treated by an alkaline solution, FIG. 6B shows a SEM image of the surface of the Si wafer after being treated by an acidic solution and FIG. 6C shows a SEM image of the surface of the Si wafer after being processed using the surface treatment method of FIG. 3 in accordance with an embodiment;

FIG. 7 shows a plot of average surface roughness of Si wafer samples processed with various surface treatment processes in accordance with an embodiment;

FIG. 8 shows plots of open circuit voltages (V_{OC}) in mV, Fill Factors (FF) in percentage (%) and specific contact resistivities (ρ_{c}) in mΩ·cm² for solar cell samples processed with various surface treatment processes in accordance with an embodiment;

FIG. 9 shows plots of open circuit voltages (V_{OC}) in mV, Fill Factors (FF) in percentage (%) and solar cells efficiencies (Eff) in percentage (%) for solar cell samples processed with various surface treatment processes in accordance with an embodiment;

FIGS. 10A and 10B show three-dimensional (3D) images of a surface of a Si layer after a surface treatment process, where FIG. 10A shows a 3D microscopy image of a surface of a Si layer after being treated in an inline wet chemical tool and FIG. 10B shows a 3D microscopy image of a surface of a Si layer after being treated in a batch wet chemical tool in accordance with an embodiment;

FIG. 11 shows a plot of average surface roughness in microns (μm) for Si wafer samples processed using an inline wet chemical tool and using a batch wet chemical tool in accordance with an embodiment;

FIG. 12 shows a plot of open circuit voltages (V_{OC}) in mV for solar cell samples processed in an inline wet chemical tool and in a batch wet chemical tool in accordance with an embodiment;

FIG. 13 shows a plot of solar cell current densities (J_{SC}) in mA/cm² for solar cell samples processed in an inline wet chemical tool and in a batch wet chemical tool in accordance with an embodiment;

FIG. 14 shows a plot of Fill Factors (FF) in percentage (%) for solar cell samples processed in an inline wet chemical tool and in a batch wet chemical tool in accordance with an embodiment;

FIG. 15 shows a plot of solar cells efficiencies (Eff) in percentage (%) for solar cell samples processed in an inline wet chemical tool and in a batch wet chemical tool in accordance with an embodiment;

FIG. 16 shows a plot of series resistances (Rₛₑᵣᵢₑₛ) in Ω·cm² for solar cell samples processed in an inline wet chemical tool and in a batch wet chemical tool in accordance with an embodiment; and

FIG. 17 shows a plot of specific contact resistivities (ρ_{c}) in mΩ·cm² for samples processed in an inline wet chemical tool and in a batch wet chemical tool in accordance with an embodiment.

### DETAILED DESCRIPTION

An exemplary embodiment relates to a surface treatment method for forming a passivated contact of a solar cell.

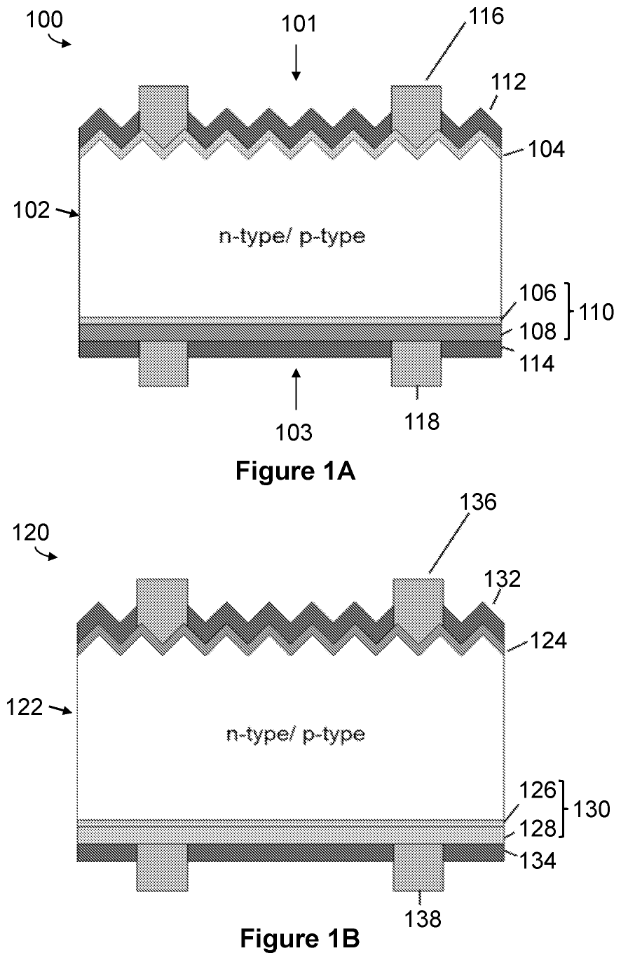

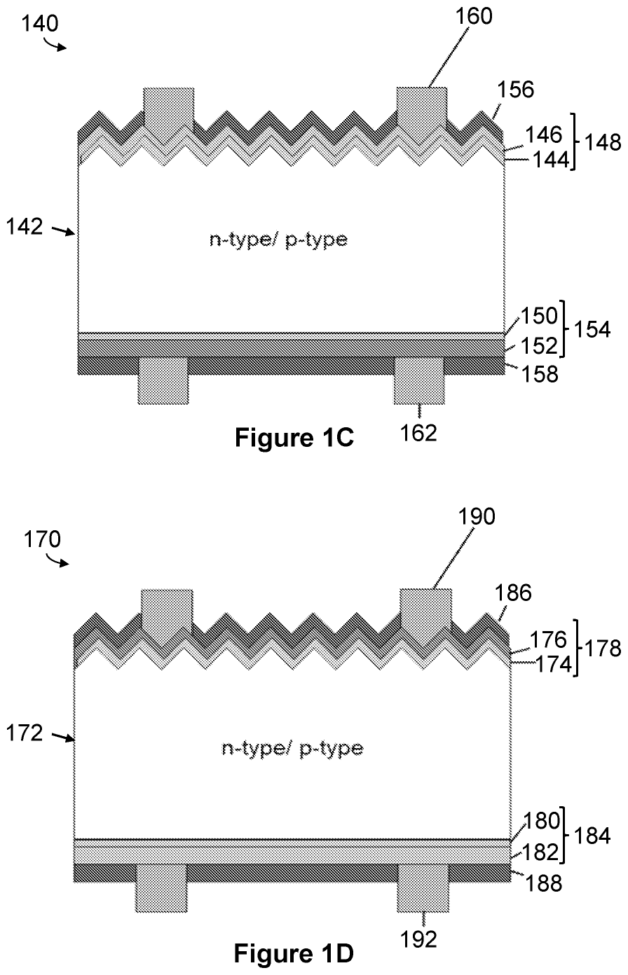

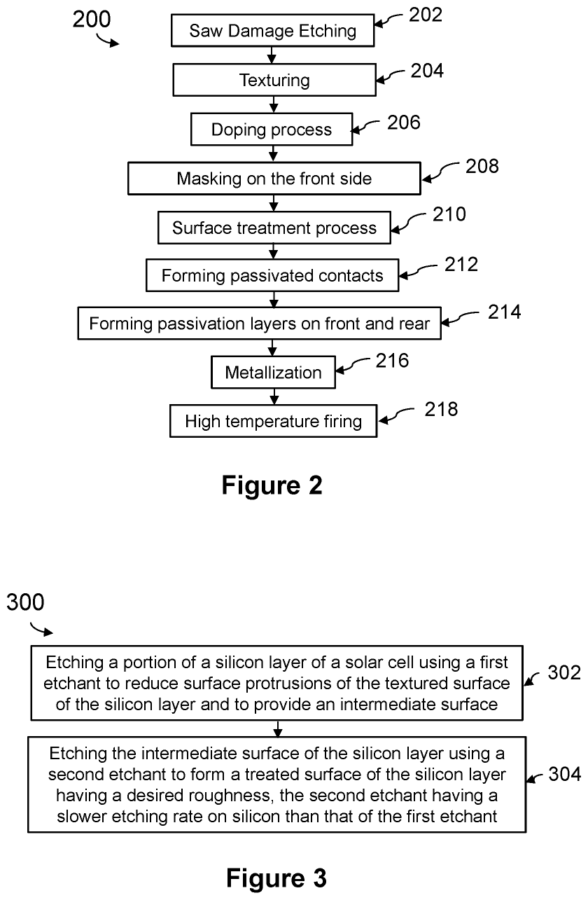

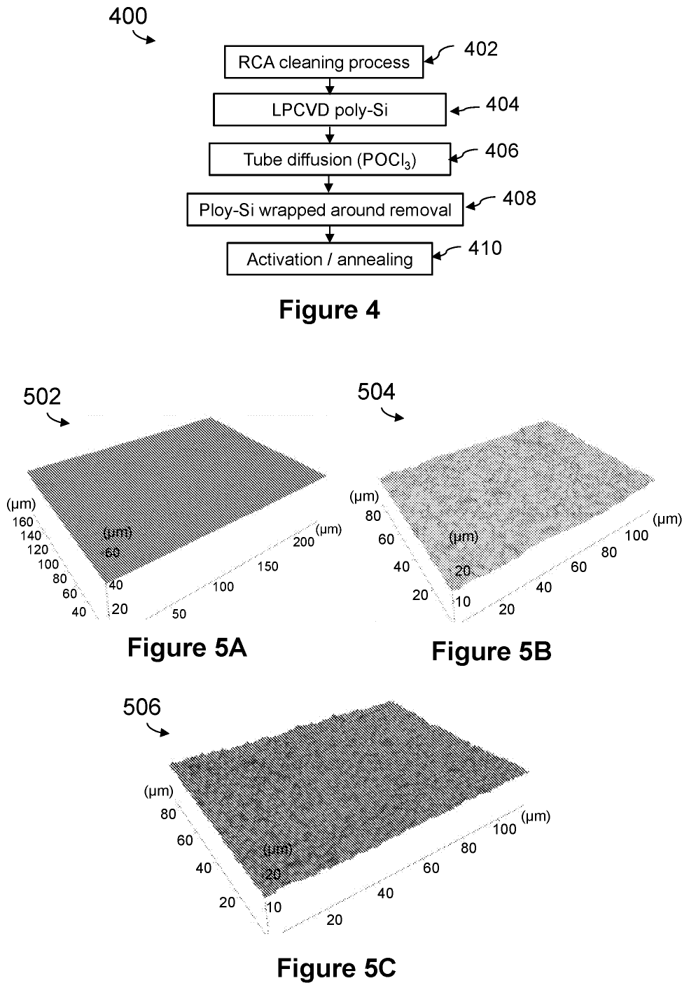

FIGS. 1A, 1B, 1C and 1D show examples of solar cell architectures for which the surface treatment method can be incorporated. An exemplary fabrication process for one of these solar cell architectures is then described in relation to FIG. 2. FIG. 3 describes the surface treatment method for forming a passivated contact of a solar cell in accordance with an embodiment, while FIG. 4 describes an exemplary process flow for forming a passivated contact of a solar cell. Experiments were performed on solar cells fabricated using the method of FIG. 2 with varying surface treatment processes and tools. These results are shown and discussed in relation to FIGS. 5A to 17.

FIGS. 1A, 1B, 1C and 1D show schematic structures of a solar cell in accordance with embodiments. Each of these solar cells has a front side arranged to receive incident light and a rear side. With reference to the solar cell 100 of FIG. 1A, the front side of the Si layer 102 refers to a top side 101 of the Si layer 102, while a rear side of the Si layer 102 refers to a bottom side 103 of the Si layer 102.

FIG. 1A shows a bifacial solar cell 100 which includes a crystalline silicon (Si) layer 102 with a front side p⁺ emitter layer 104 formed on a textured front side of the Si layer 102. In the present embodiment, the front side p⁺ emitter layer 104 is formed by thermal diffusion using a gaseous or liquid source. In other embodiments, other doping processes using a spin-on-dopant source, a solid diffusion source (BSG), or by ion-implantation may be used. The Si layer 102 is n-type in the present embodiment but it can be p-type in another embodiment. The front side p⁺ emitter layer 104 is boron doped, but it should be appreciated that other suitable p⁺ emitter layers can be formed in other embodiments. On a surface of a rear side of the Si layer 102, a rear surface dielectric tunnel layer 106 comprising silicon oxide (SiOₓ) is formed. The solar cell 100 also comprises a doped semiconductor layer 108 deposited on the rear surface dielectric tunnel layer 106. In the present embodiment, the doped semiconductor layer 108 comprises a n⁺ doped (e.g. phosphorous doped) polysilicon (poly-Si) layer. The dielectric tunnel layer 106 and the doped semiconductor layer 108 form a passivated contact 110. As shown in FIG. 1A, a front passivation layer 112 is deposited on the front side p⁺ emitter layer 104 and a rear passivation layer 114 is deposited on the doped semiconductor layer 108. In the present embodiment, the front passivation layer 112 comprises a stack of AlOₓ and SiNₓ and the rear passivation layer 114 comprises only silicon nitride (SiNₓ). However, in other embodiments, the front and rear passivation layers may each comprise a stack of one or more thin film layers (e.g. including one or more of AlOₓ, SiNₓ, SiOₓ, MgOₓ, LiF and other such thin layers). The solar cell 100 further comprises a front metal contact layer 116 deposited on the front passivation layer 112 and a rear metal contact layer 118 deposited on the rear passivation layer 114. The metal contact layers 116, 118 comprise conventional high-temperature fire-through screen printing pastes so that the metal contact layers 116, 118 formed are in electrical contact with the p⁺ emitter layer 104 and the doped semiconductor layer 108, respectively.

While FIG. 1A shows the solar cell 100 with the front side p⁺ emitter layer 104 and a rear passivated contact having a n⁺ poly-Si layer 108, FIG. 1B shows another solar cell 120 with a front side n⁺ emitter layer and a rear passivated contact having a p⁺ poly-Si layer. The solar cells for FIGS. 1A and 1B are similar except for the polarities of the front side emitter layers, the silicon layers and the poly-Si layers.

Accordingly, FIG. 1B shows a bifacial solar cell 120 which includes a crystalline silicon (Si) layer 122 with a front side n⁺ emitter layer 124 formed on a textured front side of the Si layer 122. In the present embodiment, the front side n⁺ emitter layer 124 is formed by thermal diffusion using a gaseous or liquid source. In other embodiments, other suitable doping processes such as spin on dopant source, doping processes using a solid diffusion source (BSG), ion-implantation or other such doping processes may be used. The Si layer 122 is p-type in the present embodiment but it can be n-type in another embodiment. The front side n⁺ emitter layer 124 is phosphorous doped, but it should be appreciated that other suitable n⁺ emitter layers can be formed in other embodiments. On a surface of a rear side of the Si layer 122, a rear surface dielectric tunnel layer 126 comprising silicon oxide (SiOₓ) is formed. The solar cell 120 also comprises a doped semiconductor layer 128 deposited on the rear surface dielectric tunnel layer 126. In the present embodiment, the doped semiconductor layer 128 comprises a p⁺ doped (e.g. boron doped) polysilicon (poly-Si) layer. The dielectric tunnel layer 126 and the doped semiconductor layer 128 form a passivated contact 130. As shown in FIG. 1B, a front passivation layer 132 is deposited on the front side n⁺ emitter layer 124 and a rear passivation layer 134 is deposited on the doped semiconductor layer 128. In the present embodiment, each of the front passivation layer 132 and the rear passivation layer 134 comprises silicon nitride (SiNₓ). However, in other embodiments, the front and rear passivation layers may each comprise a stack of one or more thin film layers (e.g. including one or more of AlOₓ, SiNₓ, SiOₓ, MgOₓ, LiF and other such thin layers). The solar cell 120 further comprises a front metal contact layer 136 deposited on the front passivation layer 132 and a rear metal contact layer 138 deposited on the rear passivation layer 134. The metal contact layers 136, 138 comprise conventional high-temperature fire-through screen printing pastes so that the metal contact layers 136, 138 formed are in electrical contact with the n⁺ emitter layer 124 and the doped semiconductor layer 128, respectively.

FIGS. 1C and 1D each shows a solar cell having passivated contacts on both a front side and a rear side of a Si wafer or layer.

FIG. 1C shows a bifacial solar cell 140 which includes a crystalline silicon (Si) layer 142 with a textured front side. The Si layer 142 is n-type in the present embodiment but it can be p-type in another embodiment. Differing from the solar cell 100, the solar cell 140 includes a front side passivated contact in place of the front side p⁺ emitter layer 104. Accordingly, as shown in FIG. 1C, a front side dielectric tunnel layer 144 comprising silicon oxide (SiOₓ) is formed on a surface of the front side of the Si layer 142. A front side doped semiconductor layer 146 is deposited on the front side dielectric tunnel layer 144 and together these layers 144, 146 formed a front side passivated contact 148. In the present embodiment, the front side doped semiconductor layer 146 comprises a p⁺ doped (e.g. boron doped) polysilicon (poly-Si) layer. On a surface of a rear side of the Si layer 142, a rear side dielectric tunnel layer 150 comprising silicon oxide (SiOₓ) is formed. The solar cell 140 also comprises a rear side doped semiconductor layer 152 deposited on the rear side dielectric tunnel layer 150. In the present embodiment, the rear side doped semiconductor layer 152 comprises a n⁺ doped (e.g. phosphorous doped) polysilicon (poly-Si) layer. The rear side dielectric tunnel layer 150 and the rear side doped semiconductor layer 152 form a rear side passivated contact 154. As shown in FIG. 1C, a front passivation layer 156 is deposited on the front side passivated contact 148 and a rear passivation layer 158 is deposited on the rear side passivated contact 154. In the present embodiment, each of the front passivation layer 156 and the rear passivation layer 158 comprises silicon nitride (SiNₓ). However, in other embodiments, the front and rear passivation layers may each comprise a stack of one or more thin film layers (e.g. including one or more of AlOₓ, SiNₓ, SiOₓ, MgOₓ, LiF and other such thin layers). The solar cell 140 further comprises a front metal contact layer 160 deposited on the front passivation layer 156 and a rear metal contact layer 162 deposited on the rear passivation layer 158. The metal contact layers 160, 162 comprise conventional high-temperature fire-through screen printing pastes so that the metal contact layers 160, 162 formed are in electrical contact with the front side doped semiconductor layer 146 and the rear side doped semiconductor layer 152, respectively.

FIG. 1D shows a bifacial solar cell 170 comprising a front passivated contact having a n⁺ poly-Si layer and a rear passivated contact having a p⁺ poly-Si layer. The solar cell 170 of FIG. 1D differs from the solar cell 140 of FIG. 1C in that the polarities of the poly-Si layers on the front side and the rear side of the solar cell 170 have been inverted.

As shown in FIG. 1D, the bifacial solar cell 170 includes a crystalline silicon (Si) layer 172 with a textured front side. The Si layer 172 is p-type in the present embodiment but it can be n-type in another embodiment. On a front side of the Si layer 172, a front side dielectric tunnel layer 174 comprising silicon oxide (SiOₓ) is formed on a surface of the front side of the Si layer 172. A front side doped semiconductor layer 176 comprising a n⁺ doped (e.g. phosphorus doped) polysilicon (poly-Si) layer is deposited on the front side dielectric tunnel layer 174, and together these layers 174, 176 formed a front side passivated contact 178. On a surface of a rear side of the Si layer 172, a rear side dielectric tunnel layer 180 comprising silicon oxide (SiOₓ) is formed. A rear side doped semiconductor layer 182 comprising a p⁺ doped (e.g. boron doped) polysilicon (poly-Si) layer is deposited on the rear side dielectric tunnel layer 180. The rear side dielectric tunnel layer 180 and the rear side doped semiconductor layer 182 form a rear side passivated contact 184. As shown in FIG. 1D, a front passivation layer 186 is deposited on the front side passivated contact 178 and a rear passivation layer 188 is deposited on the rear side passivated contact 184. In the present embodiment, each of the front passivation layer 186 and the rear passivation layer 188 comprises silicon nitride (SiNₓ). However, in other embodiments, the front and rear passivation layers may each comprise a stack of one or more thin film layers (e.g. including one or more of AlOₓ, SiNₓ, SiOₓ, MgOₓ, LiF and other such thin layers). The solar cell 170 further comprises a front metal contact layer 190 deposited on the front passivation layer 186 and a rear metal contact layer 192 deposited on the rear passivation layer 188. The metal contact layers 190, 192 comprise conventional high-temperature fire-through screen printing pastes so that the metal contact layers 190, 192 formed are in electrical contact with the front side doped semiconductor layer 176 and the rear side doped semiconductor layer 182, respectively.

FIG. 2 is a flowchart showing steps of a method 200 for fabricating the solar cell 100 of FIG. 1A in accordance with an embodiment. It should be appreciated that this is an exemplary embodiment for illustrating how embodiments of the surface treatment method of the present disclosure can be incorporated within a process flow for fabricating a solar cell, and it is not meant to be limiting. A skilled person would appreciate that the surface treatment method for forming passivated contacts in a solar cell can be incorporated in a similar manner in other process flows.

In this embodiment, an n-type crystalline silicon (Si) wafer is used as a starting substrate for fabricating the solar cell 100. As would be appreciated by the skilled person in the art, preparatory steps (e.g. cleaning the Si wafer surface) may be necessary before each fabrication step, and these preparatory steps have been omitted for clarity and succinctness of the present method 200.

In a step 202, a saw damage etch (SDE) is performed on the Si wafer 102 to reduce surface damages induced by an earlier sawing process performed on the Si wafer, e.g. to cut the Si wafer into ingots. The SDE involves a wet alkaline etch process using sodium hydroxide (NaOH), potassium hydroxide (KOH), or tetramethylammonium hydroxide (TMAH) diluted in de-ionised water as the etch solution.

Following the SDE performed in the step 202, the Si layer 102 of the solar cell 100 is textured in a step 204. Texturing of the Si layer 102 is performed on the front side and the rear side of the Si layer 102, and this may comprise using a wet chemical etch comprising a low concentration (e.g. 2.5 wt %) potassium hydroxide (KOH) solution along with other additives to anisotropically etch the Si layer 102.

In a step 206, the Si layer 102 is doped to form the front side p⁺ emitter layer 104. In the present embodiment, the front side p⁺ emitter layer 104 is formed by doping the Si layer 102 using horizontal tube thermal diffusion with a dopant source (e.g. Boron tri-bromide (BBr₃)). Due to the inherent two-sided process characteristic of horizontal tube thermal diffusion, the rear side of the Si layer 102 is also doped with Boron (B). This rear side B-doped layer needs to be removed in a subsequent process step prior to forming the rear side passivated contact 110.

In a step 208, a masking layer is deposited on the front side of the Si layer 102 to protect the front side p⁺ emitter layer 104 prior to the removal of the unwanted rear-side B-doped layer formed at the rear side of the Si layer 102. In the present embodiment, the masking layer comprising SiNₓ is deposited on the p⁺ emitter layer 104 by plasma enhanced chemical vapour deposition (PECVD).

In a step 210, a surface of the rear side of the Si layer 102 is treated prior to the formation of the rear-side passivated contact 110. The surface treatment process in the step 210 involves wet-etching and may include etching using an acidic solution or a mixture of acidic solutions, or an alkaline solution or a mixture of alkaline solutions, and/or a single component etchant such as NaOCl. In the present embodiment, the surface treatment method includes a two-step etching process and this is further described in relation to FIG. 3.

In a step 212, the rear side passivated contact 110 is formed on the rear side of the solar cell 100. As described in relation to FIG. 1A, the passivated contact 110 includes the dielectric tunnel layer 106 and the doped semiconductor layer 108. Formation of the passivated contact 110 therefore involves the formation of the dielectric tunnel layer 106 and the doped semiconductor layer 108. Further detail of the step 212 is described in relation to FIG. 4.

In a step 214, the front passivation layer 112 and the rear passivation layer 114 are formed on the front side and the rear side of the Si layer 102, respectively. In the present embodiment, the front side passivation layer 112 comprises a stack of AlOₓ and SiNₓ and the rear side passivation layer 114 comprises SiNₓ which are deposited using PECVD.

In a step 216, the metal contact layers 116, 118 are deposited on the front side passivation layer 112 and the rear side passivation layer 114, respectively, using conventional screen printing technology, e.g. using a conventional high-temperature fire-through screen printing paste. In the present embodiment, the rear side metal contact layer 118 includes a silver (Ag) paste.

In a step 218, high temperature firing or annealing is performed so that the metal contact layers 116, 118 formed in the step 216 react and penetrate through the respective passivation layers 112, 114 to form electrical contact with the p⁺ emitter layer 104 and the rear side doped semiconductor layer 128, respectively.

Using the exemplary embodiment of the solar cell 100 of FIG. 1A, the passivated contact 110 formed includes a doped n⁺ polysilicon layer 108 formed over a dielectric tunnel layer 106 (e.g. an ultrathin interfacial oxide layer, SiOₓ). Owing to a specific morphology of this rear side poly-Si layer 108, special metallization pastes have been developed for use as the rear metal contact layer 118 to contact the doped n⁺ polysilicon layer 108. However, these special metallization pastes can be sensitive to the surface morphology of the rear side poly-Si layer 108 and by extension, the rear surface of the Si layer 102. A good control of the rear side etching process is therefore desired.

Further, as described in relation to the step 206 for the fabrication of the solar cell 100, the boron doping process performed at high temperature using BBr3 as a dopant source in a tube furnace is inherently a double-side dopant diffusion process. It is therefore necessary to remove the unwanted B-doped layer formed at the rear side of the Si layer 102. A surface treatment method for removing this unwanted B-doped layer while achieving the desired morphology for passivated contact formation is therefore desired. An optimal rear surface morphology for passivated contact formation should include a surface roughness which is low enough to allow for an excellent passivation for providing good open circuit voltages for solar cells, but not too low so that metal contact formed using fire-through metal pastes would still show excellent contact properties (e.g. low specific contact resistivities). A surface treatment method which allows for such a desired morphology to be achieved on a Si layer surface (e.g. rear or front) for the formation of a passivated contact in a solar cell is therefore advantageous.

To achieve the above, a two-step etching process is described in relation to a surface treatment method 300 of FIG. 3. FIG. 3 is a flowchart showing steps of the surface treatment method 300 for forming a passivated contact of a solar cell in accordance with an embodiment. The method 300 can be performed at the step 210 of FIG. 2.

In a step 302, a portion of a silicon layer of a solar cell is etched using a first etchant to reduce surface protrusions of the textured surface of the silicon layer and to provide an intermediate surface. In the present embodiment, where the rear side of the Si layer 102 is doped by boron in the doping process step 206, this unwanted B-doped layer is also removed in this first etching step 302. This may involve a KOH solution with a KOH concentration of 2 wt % to 20 wt %, and the etching step 302 being performed at a temperature range of 303 K to 358 K for a duration of 15 seconds to 3 minutes.

In a step 304, the intermediate surface of the silicon layer is etched using a second etchant to form a treated surface of the silicon layer having a desired roughness, where the second etchant has a slower etching rate on silicon than that of the first etchant. In the present embodiment, a single component etchant NaOCl is used. The NaOCl solution has a concentration of 10 wt % to 15 wt %, and the etching step 304 is performed at a temperature range of 303 K to 358 K for 5 minutes to 15 minutes.

FIG. 4 is a flowchart showing steps of a method 400 for forming a passivated contact of the solar cell 100 of FIG. 1A in accordance with an embodiment. The method 400 can be performed at the step 212 of the method 200 of FIG. 2. The passivated contact 110 formed not only provides an excellent surface passivation towards the crystalline silicon layer but also provides a reasonable low contact resistivity (in the order of several to some ten mΩ·cm2) and enables a high carrier extraction selectivity (i.e. are able to extract only electrons or only holes at the contact, with a carrier selectivity higher than e.g. 12).

In a step 402, the RCA (Radio Corporation of America) cleaning process is performed on the rear side of the Si layer 102. The RCA cleaning process is a known standard cleaning process in the art, and it comprises (i) a first step of removal of organic contaminants using a mixture of aqueous ammonia (NH3) and aqueous hydrogen peroxide (H2O2), (ii) a second step of removal of thin oxide layer using aqueous hydrofluoric acid (HF), and (iii) a third step of removal of ionic contamination using a mixture of hydrochloric acid (HCl) and aqueous hydrogen peroxide (H2O2). After the third step of removal of ionic contamination, a thin passivating layer of SiOx is wet-chemically formed and left on the rear surface of the Si layer 102 which protects the surface from subsequent contamination. This thin passivating layer of SiOx may also be used as the rear surface dielectric tunnel layer 106 of the solar cell 100.

In a step 404, poly-Si is formed on the thin passivating layer of SiOx by low pressure chemical vapour deposition (LPCVD). In another embodiment, the poly-Si can be deposited using plasma enhance chemical vapour deposition (PECVD).

In a step 406, in the present embodiment, the poly-Si formed in the step 404 is doped by phosphorus using a thermal tube diffusion process with POCl3 precursor to form n+ doped poly-Si. The n+ doped poly-Si forms the doped semiconductor layer 108 of the solar cell 100, and functions to selectively extract electrons in the passivated contact 110.

In a step 408, unwanted poly-Si formed in the step 404 which have wrapped around a front surface of the solar cell is removed. This removal process can be performed using dry etching or wet etching.

In a step 410, an annealing step is performed to activate the phosphorous dopants in the n+ poly-Si layer. The annealing step is performed at a temperature range of 700° C. to 800° C.

To demonstrate the efficacy of the surface treatment method 300 in fabricating high efficiency solar cells, solar cells with a same structure as the solar cell 100 of FIG. 1A were fabricated using different surface treatment methods for the step 210. For the following experimental results, Si solar cells which incorporate poly-Si based passivated contacts on the rear were fabricated using low resistivity (1-1.5 Ω·cm) large area (M2) crystalline Si wafers. These Si solar cells were prepared according to the method 200 of FIG. 2 using in-line wet chemical tools or batch wet chemical tools for the surface treatment step 210. For the surface treatment step 210, four variations were used: (i) an alkaline-only etch, (ii) an acid-only etch, (iii) an advanced surface process 1 using the two-step etching process of method 300 where the first etchant is an alkaline, and (iv) an advanced surface process 2 using the two-step etching process of method 300 where the first etchant is an acid mixture. Details of the advanced surface processes 1 and 2 are shown at Table 1 below. In the present embodiment, for the advanced surface process 1, it involves a first etching step using 20 wt % KOH solution at 70° C. for 30 seconds, followed by a second etching step using a 15 wt % NaOCl at 70° C. for 15 minutes. In the present embodiment, for the advanced surface process 2, it involves a first etching step using a mixture of 38 wt % HNO3 and 9 wt % HF at room temperature for 1 minute, followed by a second etching step using a 12 wt % NaOCl at 70° C. for 10 minutes.

TABLE 1:
Processing parameters range for tailoring surface morphologies
using advanced chemical processing

| Chemical | | | | Time |
|---|---|---|---|---|
| Process | Step: Chemical | Conc [wt %] | Temp [K] | [seconds] |
| Advanced | Step-1: HNO₃ | 25-45 | 291-303 | 30-180 |
| surface | Step-1: HF | 2-10 | 291-303 | 30-180 |
| process 2 | Step-2: NaOCl | 10-15 | 303-358 | 300-900 |
| Advanced | Step-1: KOH | 2-20 | 303-358 | 15-180 |
| surface | Step-2: NaOCl | 10-15 | 303-358 | 300-900 |
| process 1 | | | | |

Variations (i) and (ii) above serve to replicate existing methods for etching Si layers for comparison with the two-step etching process of the present disclosure. Particularly, for PERC cells, removing the doped Si layer on rear surfaces (e.g. in the step 210) can be performed using KOH or HNO₃+HF. For B-doped Si, it is difficult to etch using an alkaline solution as compared to P-doped Si and so the use of an acidic mixture of HNO₃+HF is preferred. Isotropic etching of the B-doped or P-doped Si layers is typically performed at elevated temperatures (e.g. 60-80° C.) where the etch rates are relatively high and vary from 0.5-1 μm/min depending on the concentrations of the chemicals involved and the temperature at which the etch is performed. To ensure uniformity of temperature and concentration of the etchant mixture, the etchant mixture used has to be well mixed throughout the entire etching process. Otherwise, insufficient mixing of the chemicals may lead to a highly non-uniform etch. Moreover, the high etch rate cannot be easily controlled and it depends on a number of parameters such as a temperature, concentrations of the etchants used, uniform mixing of the etchant mixture and the uniformity of doping of the carrier selective doped Si layers. Further, these acid or alkali processes leave a shiny etched Si surface which could adversely impact the contact properties of screen-printed and fired through contacts. Since the fire-through pastes designed for contacting poly-Si are extremely sensitive to surface roughness, it is therefore very difficult to achieve good passivated contacts given the difficulty in controlling the morphology and roughness of the etched surface using these acid or alkali processes. Although existing etching processes using such alkaline and/or acid mixtures are being continuously developed, further improvements in these processes will require additional capital investment, e.g. in the form of a new inline wet chemical processing equipment.

For variation (i), a KOH solution having a concentration range of 2%-20% by weight (i.e. wt %) can be used at a temperature ranging from 30° C. to 85° C. In the present embodiment, the surface treatment method for variation (i) includes using a 15 wt % KOH solution at 70° C. for 3 minutes. For variation (ii), an acidic mixture of HF—HNO₃ having a HF concentration of 2%-10% by weight and a HNO₃ concentration of 25%-45% by weight can be used at room temperature (e.g. 20° C. to 30° C.). In the present embodiment, the surface treatment method for variation (ii) includes using a 40 wt % HNO₃ and 10 wt % HF mixture at room temperature for 3 minutes. Depending on the process parameters employed, the duration of etch performed for the variations (i) and (ii) may vary between 15 seconds to 3 minutes.

Referring back to the present two-step etching process of variations (iii) and (iv), in the present embodiment, the second etching step of these variations each involves the use of a single component NaOCl etchant. Use of a single component etchant makes the equipment design simpler, eliminates the need to ensure well mixing of the etchant during the etching process, and offers better temperature control to provide for an etch rate which is uniform with time and that can be controlled easily. The non-hazardous nature of the NaOCl also means that minimal treatment of chemical/etch waste produced is required before disposal. This further reduces the process cost and environmental impact. These advanced two-step etching processes can also be implemented using existing wet chemical equipment (e.g. inline wet chemical tool or batch wet chemical tool), minimising investment required for any new etching equipment. The two-step etching processes developed for surface treatment of the Si layer surface prior to the passivated contact formation is simple, robust, and highly flexible. In the present embodiment, this two-step etching process can be adopted as required in existing batch wet chemical tools for etching doped silicon layers to obtain a desired surface morphology for forming n-type passivated contacts. Because of the slower, uniform etch rate of the second etching step as compared to the first etching step, thickness of an order of a few nanometres can be etched accurately by adjusting the duration of the second etching step. Accordingly, while the first etching step of this two-step etch process provides a quick way to remove the unwanted doped semiconductor layer formed at the rear side of the Si layer 102, the second etching step provides an accurate and controlled way to provide a surface with a desired roughness which is smooth enough to minimise degradation in the passivation properties while being rough enough to from excellent contacts with the fire-through metal pastes.

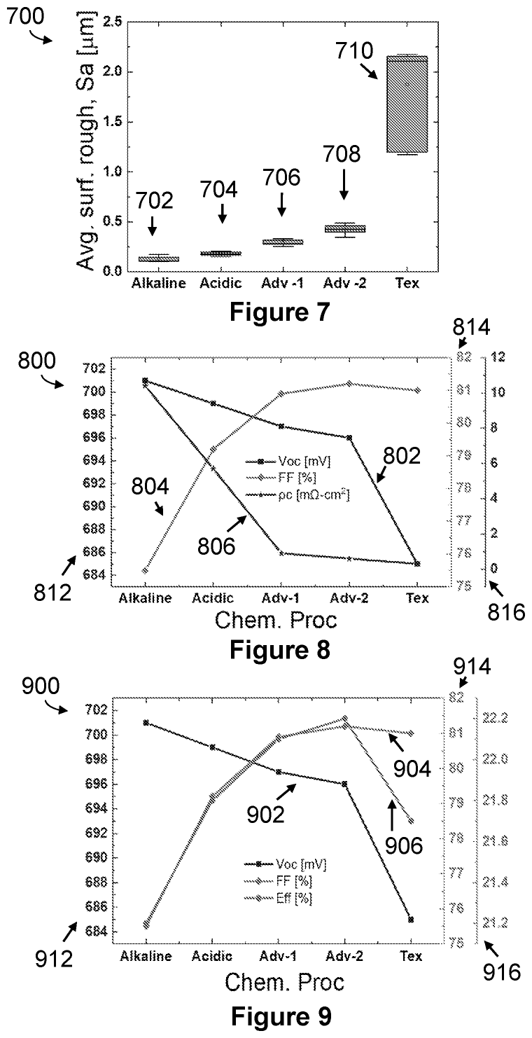

FIGS. 5A to 9 relate to experimental results obtained using various surface treatment methods for the step 210, namely: (i) an alkaline-only etch, (ii) an acid-only etch, (iii) an advanced surface process 1 using the two-step etching process of method 300 where the first etchant is an alkaline, and (iv) an advanced surface process 2 using the two-step etching process of method 300 where the first etchant is an acid mixture. In addition, FIGS. 7 to 9 show additional experimental results in relation to properties of a solar cell with a textured rear surface, where the textured rear surface may be obtained by an anisotropic etch using 2.5 wt % KOH solution along with other additives as the surface treatment method, similar to that for the step 210. Further, the variations (i), (ii) and (iv) were performed using inline wet chemical tool, while the variations (iii) and the texturing surface treatment were performed using batch wet chemical tool.

FIGS. 5A, 5B and 5C show three-dimensional (3D) images of a surface of a Si layer after undergoing a surface treatment process (e.g. the step 210) in accordance with an embodiment.

FIG. 5A shows a 3D microscopy image 502 of a surface of a Si layer after being treated by a KOH solution under the conditions of variation (i) as described above, FIG. 5B shows a 3D microscopy image 504 of a surface of a Si wafer after being treated by a HF—HNO₃ mixture under the conditions of variation (ii) as described above, and FIG. 5C shows a 3D microscopy image of a surface of a Si wafer after being treated using the advanced surface process 1 as described above. From the 3D microscopy images 502, 504 and 506, it is clear that etching of the Si layer using only the alkaline KOH solution produces the smoothest surface among the three, while the use of the two-step etching process produces the roughest surface among the three.

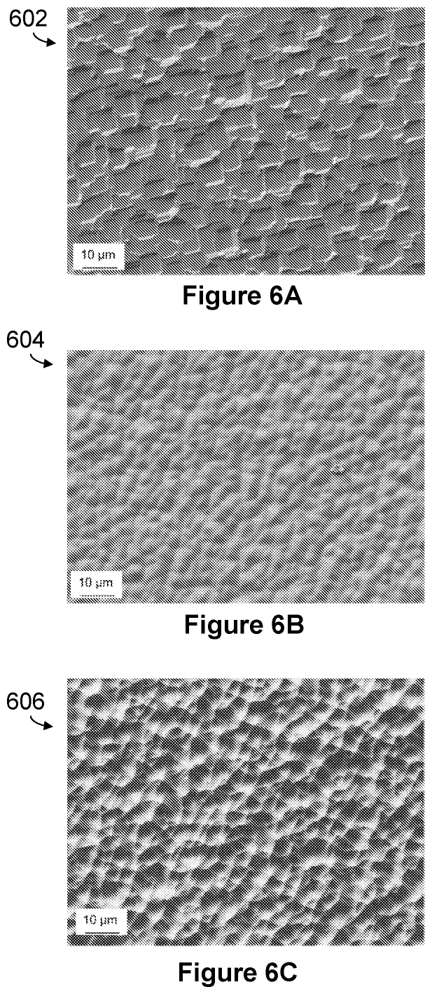

FIGS. 6A, 6B and 6C show scanning electron microscopy (SEM) images of the surfaces of the Si layer corresponding to FIGS. 5A, 5B and 5C respectively. FIG. 6A shows the SEM image 602 of the surface of the Si layer after being treated by the KOH solution, FIG. 6B shows the SEM image 604 of the surface of the Si layer after being treated by the acidic HF—HNO₃ mixture and FIG. 6C shows the SEM image 606 of the surface of the Si layer after being treated using the advanced surface process 1 (i.e. alkaline KOH+NaOCl) as described above. The results obtained for the SEM images 602, 604 and 606 are consistent with the 3D microscopy images as shown in FIGS. 5A to 5C.

FIG. 7 shows a plot 700 of an average surface roughness of Si wafer samples processed with various surface treatment processes in accordance with an embodiment. In the plot 700, the average surface roughness of the Si wafer samples which underwent the alkaline KOH treatment (i.e. variation 1, and labelled as “Alkaline”), the acidic HF—HNO₃ treatment (i.e. variation 2, and labelled as “Acidic”), the advanced surface process 1 (i.e. variation 3, and labelled as “Adv-1”), the advanced surface process 2 (i.e. variation 4, and labelled as “Adv-2”), and the texturing process (labelled as “Tex”) were shown. The surface roughness for each of these sample were measured using a 3-D microscope (Zeta-300, Zeta Instruments, USA). As shown in the plot 700, the average surface roughness 702 of the Si sample which underwent the alkaline KOH treatment and the average surface roughness 704 of the Si sample which underwent the acidic HF—HNO₃ treatment are each about 0.1 μm to 0.2 μm, the average surface roughness 706 of the Si sample which underwent the advanced surface process 1 and the average surface roughness 708 of the Si sample which underwent the advanced surface process 2 are each about 0.25 μm to 0.45 μm, while the average surface roughness 710 of the Si sample which underwent the texturing process is about 1.2 to 2.2 μm.

FIG. 8 shows plots 800 of open circuit voltages (V_{OC}) in mV, Fill Factors (FF) in percentage (%) and specific contact resistivities (ρ_{c}) in mΩ·cm² for n-type solar cell samples processed with various surface treatment processes in accordance with an embodiment. The specific contact resistivity (ρ_{c}) was measured using the Transfer Length Measurement (TLM) method for Ag contacts formed on n⁺ poly-Si (e.g. phosphorous doped poly-Si). As shown in FIG. 8, the plot 802 relates to the V_{OC} for the various samples with the scale bar 812 measured in units of mV, the plot 804 relates to the FF for the various samples with the scale bar 814 measured in units of percentage (%), and the plot 806 relates to the ρ_{c} for the various samples with the scale bar 816 measured in units of mΩ·cm². For the samples used in the present experiment, a fire-through Ag paste designed to contact n⁺ poly-Si was used. This paste generally exhibits high sensitivity to surface morphology.

FIG. 9 shows plots 900 of open circuit voltages (V_{OC}) in mV, Fill Factors (FF) in percentage (%) and solar cells efficiencies (Eff) in percentage (%) for n-type solar cell samples processed with various surface treatment processes in accordance with an embodiment. As shown in FIG. 9, the plot 902 relates to the V_{OC} for the various samples with the scale bar 912 measured in units of mV, the plot 904 relates to the FF for the various samples with the scale bar 914 measured in units of percentage (%), and the plot 906 relates to the Eff for the various samples with the scale bar 916 measured in units of percentage (%).

As shown in the plots 800, 900 of FIGS. 8 and 9, the solar cells processed through the advanced chemical processes (i.e. “Adv-1” and “Adv-2”) show an approximate improvement in absolute efficiency (Eff) of >1% when compared with the solar cell surface treated using only alkaline KOH (i.e. “Alkaline”) prior to passivated contact formation. As shown in the plots 800, 900, almost all of the efficiency gained in the solar cells processed through the advanced chemical processes was due to an improved fill factor (FF) of the solar cells as compared to those processed using only alkaline KOH (i.e. “Alkaline”). This can be explained as follows. Although the smoother surface of the Si layer obtained using the only alkaline KOH surface treatment for forming passivated contacts leads to a higher solar cell voltage V_{OC}, the FF of these solar cells is still poorer due to the poorer contacts formed on the n⁺ poly-Si layer 108 as a result of the smoother surface. On the other hand, the slightly lower V_{OC} of the solar cells processed through the advanced chemical processes could be attributed to the slightly rougher surface on which the passivated contacts were formed. However, in the solar cells processed through the advanced chemical processes, the loss in V_{OC} is more than compensated by the gain in FF. The lower FF of the solar cells processed with only alkaline KOH as compared to those processed with acidic HF—HNO₃ or the advanced chemical processes can largely be attributed to the higher contact resistance of the passivated contacts formed due to the smoother surface. For the solar cells processed with texturing, although these samples achieve the lowest pc, the gain in FF fails to compensate for the loss in the V_{OC} in these samples. Therefore, overall, solar cells processed with the advanced chemical processes resulted in solar cells having the highest efficiencies Eff as shown in the plot 900. Given that the solar cell samples for all these cases have similar front structure, the different results obtained in the plots 800, 900 as shown in FIGS. 8 and 9 are therefore in relation to the rear passivated contact formation. Hence, it is clear that the advanced chemical processes (i.e. the two-step etching surface treatment method) developed in the present disclosure tailored for a desired surface morphology which leads to significantly improved passivated contacts formed to achieve solar cells having the highest FF and cell efficiencies. Further, it can also be noted that the advanced chemical processes can be applied in the inline wet chemical tool or the batch wet chemical tool to achieve similar results.

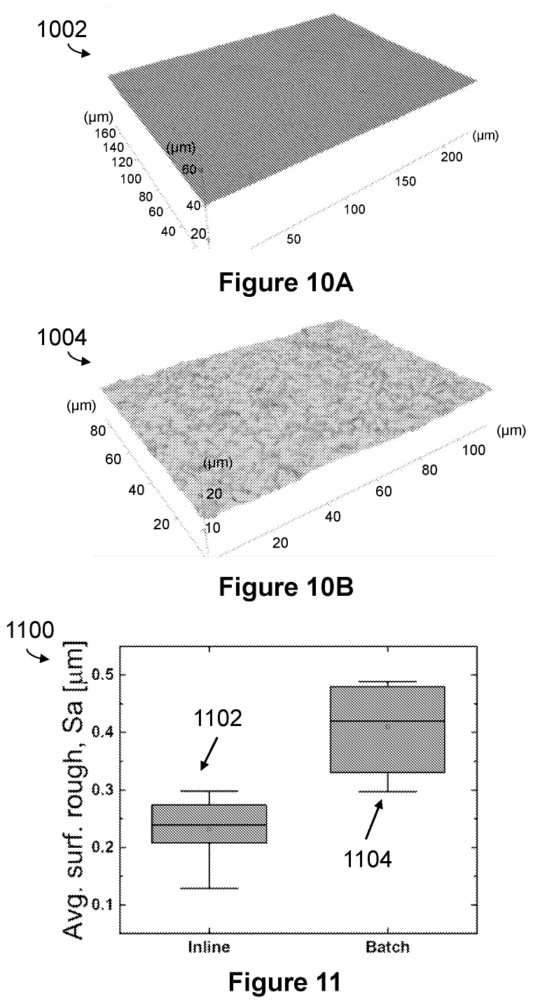

Besides comparing solar cells fabricated using different surface treatment methods for forming the passivated contacts, solar cells fabricated using two different processing routes, an inline wet chemical tool and a batch wet chemical tool, were also investigated. In the present embodiment, the inline wet chemical tool involves etching using an alkaline-only chemistry (although an acid base etchant can also be used in other embodiments), while the batch wet chemical tool involves the two-step etching process as described above (e.g. using Adv-1). An inline wet chemical tool typically involves transporting a wafer to be etched on rollers dipped in an etchant so that only a single side of the wafer is exposed to the etchant for the etching process, while a batch wet chemical tool typically involves immersing a wafer in a bath of etchant so that the entire wafer is exposed to the etchant. In the present embodiments, the inline wet chemical tool may use KOH and/or HF etchants, while the batch wet chemical tool uses the two-step etching process as earlier described. The advantage of the batch wet chemical tool lies in its flexibility with respect to its economy, foot-print, wafer size and bath chemistry, while the advantage of using the inline wet chemical tool is a larger throughput. The two-step etching process used in the batch wet chemical tool for these embodiments may involve a first etching step using a KOH bath and a second etching step using a single component NaOCl etchant. For the first etching step, the KOH bath has a KOH concentration of 15%-20% by weight (i.e. wt %) and a temperature of 60° C. to 80° C. The first etching step was performed for 15 to 45 seconds, or 15 to 30 seconds. The second etching step involves etching the wafers in a NaOCl bath having a NaOCl concentration of 10%-15% by weight and at a temperature of 70° C. to 80° C. for 10-15 minutes. Particularly, in the present embodiment, the inline wet chemical tool involves an alkaline-only process using a 15 wt % KOH at 75° C. for 3 min, while the batch wet chemical tool involves a two-step etching process where a first etching step uses a 15 wt % KOH at 75° C. for 45 seconds followed by a second etching step which uses a 15 wt % NaOCl at 75° C. for 15 minutes. In the present embodiments, the processes performed using the inline and/or batch wet chemical tools are controlled within a 5° C. temperature window, which can be considered as robust for an industrial process. FIGS. 10A to 17 shows the experimental results obtained for these solar cells.

FIGS. 10A and 10B show three-dimensional (3D) images of a surface of a Si layer after a surface treatment process in accordance with an embodiment. FIG. 10A shows a 3D microscopy image 1002 of a surface of a Si layer after being treated using the inline wet chemical tool (i.e. using the alkaline-only process) and FIG. 10B shows a 3D microscopy image 1004 of a surface of a Si layer after being treated in a batch wet chemical tool (i.e. using the two-step etching process). From the 3D microscopy images 1002 and 1004, it is clear that etching of the Si layer using the batch wet chemical tool using the two-step etching process provides a rougher surface as compared to that using the inline wet chemical tool.

FIG. 11 shows a plot 1100 of an average surface roughness for Si wafer samples processed in the inline wet chemical tool (using the alkaline-only process) and in the batch wet chemical tool (using the two-step etching process) in accordance with an embodiment. In the plot 1100, the average surface roughness of the Si wafer samples which underwent processing by the inline wet chemical tool (labelled as “Inline”) and the Si wafer samples which underwent processing by the batch wet chemical tool (labelled as “Batch”) are shown. As shown in the plot 1100, the average surface roughness 1102 of the samples processed using the inline wet chemical tool is about 0.25 μm, while the average surface roughness 1104 of the samples processed using the inline wet chemical tool is about 0.4 μm. The surface roughness for each of these samples were measured using a 3-D microscope (Zeta-300, Zeta Instruments, USA).

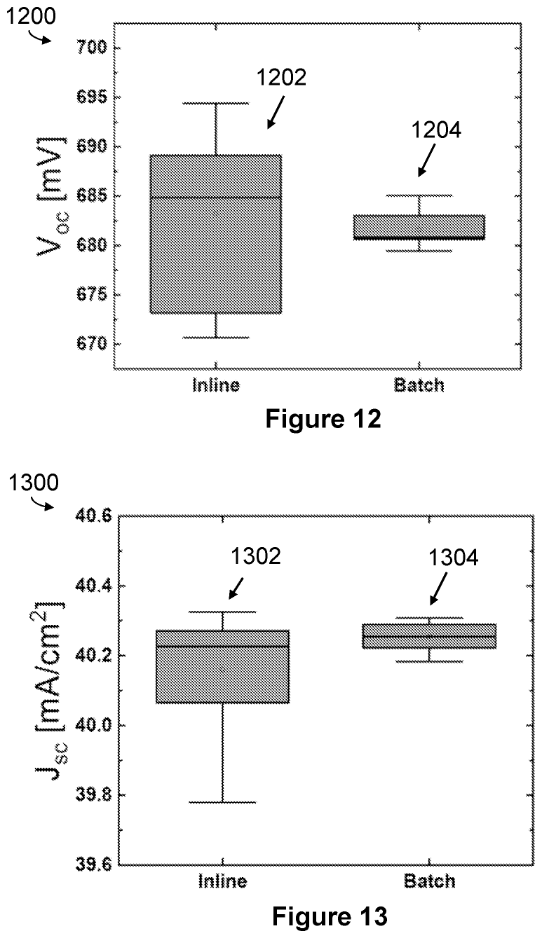

FIG. 12 shows a plot 1200 of open circuit voltages (V_{OC}) in mV for n-type solar cell samples, with n⁺ poly-Si passivated contact formed on the rear surface, processed in the inline wet chemical tool (i.e. using the alkaline-only process) and in the batch wet chemical tool (i.e. using the two-step etching process) in accordance with an embodiment. The plot 1202 is associated with the V_{OC} of samples processed using the inline wet chemical tool, while the plot 1204 is associated with the V_{OC} of samples processed using the batch wet chemical tool.

FIG. 13 shows a plot 1300 of solar cell current densities (J_{SC}) in mA/cm² for n-type solar cell samples, with n⁺ poly-Si passivated contact formed on the rear surface, processed in the inline wet chemical tool (i.e. using the alkaline-only process) and in the batch wet chemical tool (i.e. using the two-step etching process) in accordance with an embodiment. The plot 1302 is associated with the J_{SC} of samples processed using the inline wet chemical tool, while the plot 1304 is associated with the J_{SC} of samples processed using the batch wet chemical tool.

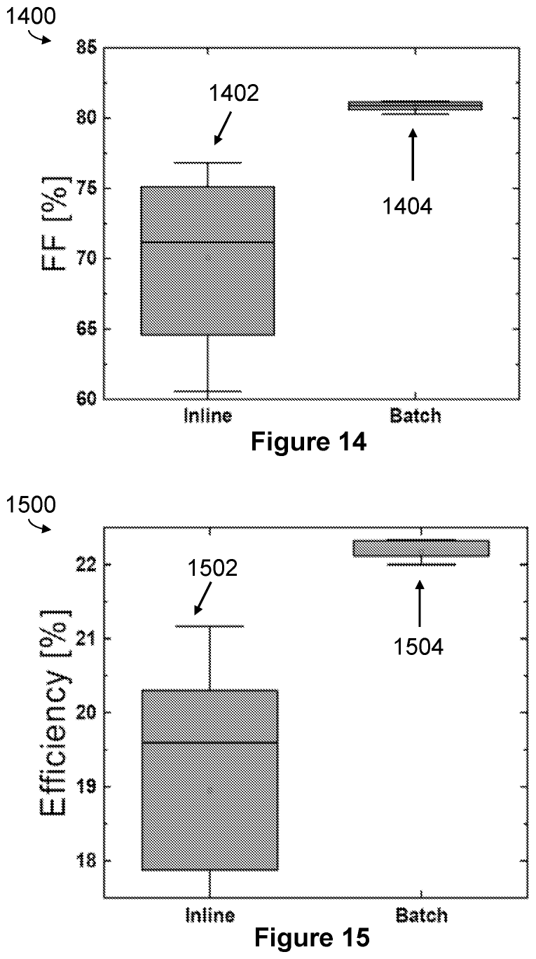

FIG. 14 shows a plot 1400 of Fill Factors (FF) in percentage (%) for n-type solar cell samples, with n⁺ poly-Si passivated contact formed on the rear surface, processed in the inline wet chemical tool (i.e. using the alkaline-only process) and in the batch wet chemical tool (i.e. using the two-step etching process) in accordance with an embodiment. The plot 1402 is associated with the FF of samples processed using the inline wet chemical tool, while the plot 1404 is associated with the FF of samples processed using the batch wet chemical tool.

FIG. 15 shows a plot 1500 of solar cells efficiencies (Eff) in percentage (%) for n-type solar cell samples, with n⁺ poly-Si passivated contact formed on the rear surface, processed in the inline wet chemical tool (i.e. using the alkaline-only process) and in the batch wet chemical tool (i.e. using the two-step etching process) in accordance with an embodiment. The plot 1502 is associated with the Eff of samples processed using the inline wet chemical tool, while the plot 1504 is associated with the Eff of samples processed using the batch wet chemical tool.

The current density-voltage (J-V) characteristics of the n-type passivated contact solar cells fabricated using the inline and batch wet chemical tools are shown in relation to FIGS. 12 to 15 above. Similar to the solar cells fabricated and measured in experiments in relation to FIGS. 7 to 9, the n⁺ poly-Si layer in these solar cells were metallized with fire-through Ag paste designed to contact n+ poly-Si which generally exhibits high sensitivity to surface morphology. As shown in FIG. 15, the solar cells processed using the batch wet chemical tool show an approximate improvement in solar cell efficiency of >2% absolute. Comparing the plots 1200, 1300 and 1400, it is observed that almost all of the efficiency gained for solar cells processed using the batch chemical tool was due to an improved fill factor (FF) of these solar cells, while the other relevant parameters such as the V_{OC} and J_{SC} of the solar cells processed using the inline wet chemical tool and the batch wet chemical tool are comparable. In fact, the V_{OC} of the solar cells processed using the batch wet chemical tool is slightly lower than those processed using the inline wet chemical tool, and this could be attributed to the slightly rougher surface formed on the rear of the Si layer for the formation of the passivated contact. However, the loss is V_{OC} for these solar cells fabricated using the batch wet chemical tool is more than compensated by the gain in FF, thereby resulting in a higher solar cell efficiency overall. Since the front surface is same in both cases, the difference in the solar cell parameters and efficiency could be attributed to the rear surface morphology only.

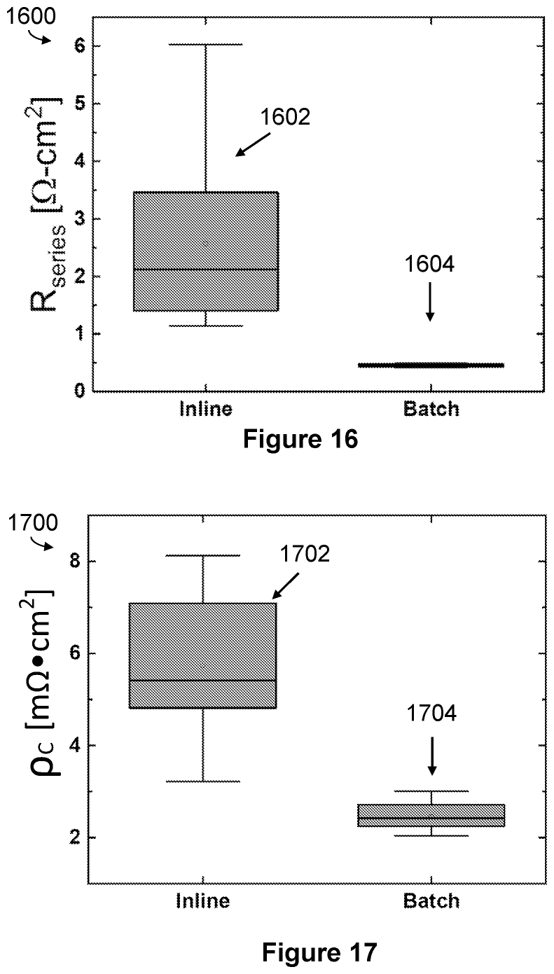

FIG. 16 shows a plot 1600 of series resistances (Rₛₑᵣᵢₑₛ) in Ω·cm² for n-type passivated contact solar cell samples with n⁺ poly-Si passivated contact on the rear surface processed in the inline wet chemical tool (i.e. using the alkaline-only process) and in the batch wet chemical tool (i.e. using the two-step etching process) in accordance with an embodiment. The plot 1602 is associated with the Rₛₑᵣᵢₑₛ of samples processed using the inline wet chemical tool, while the plot 1604 is associated with the Rₛₑᵣᵢₑₛ of samples processed using the batch wet chemical tool. As shown in FIG. 16, it is clear that the Rₛₑᵣᵢₑₛ for the solar cells processed using the inline wet chemistry tool is higher than for those processed in the batch wet chemical tool, by a factor of 4 or more. This can explain the lower FF of the solar cells processed using the inline wet chemical tool, which could largely be attributed to the higher series resistance (Rₛₑᵣᵢₑₛ) obtained in these solar cells as compared to those processed using the batch wet chemical tool.

Since the front architecture for each of these solar cells is similar, the difference in the properties obtained for solar cells processed using the inline wet chemical tool and the solar cells processed using the batch wet chemical tool is associated with the rear passivated contacts. To further analyse the difference in the properties of the rear passivated contacts, specific contact resistivity (pc) for Ag contacts formed on n⁺ poly-Si was measured using the Transfer Length Measurement (TLM) method.

FIG. 17 shows a plot 1700 of specific contact resistivities (pc) in mΩ·cm² for Ag contacts formed on n⁺ poly-Si samples processed in the inline wet chemical tool (i.e. using the alkaline-only process) and in the batch wet chemical tool (i.e. using the two-step etching process) in accordance with an embodiment. The plot 1702 is associated with the pc for Ag contacts formed on n⁺ poly-Si where the rear surface was processed using the inline wet chemical tool, while the plot 1704 is associated with the pc for Ag contacts formed on n⁺ poly-Si where the rear surface was processed using the batch wet chemical tool. As shown in the plot 1700, it is clear that surface treatment of the rear side of the Si layer using the batch wet chemical tool leads to formation of significantly improved rear passivated contacts having lower pc. This leads to a lower Rₛₑᵣᵢₑₛ, which in turn results in an improved FF and solar cell efficiency (Eff) for these solar cells.

Although the two-step etching process for surface treating the Si wafer prior to forming passivated contacts was shown in standalone solar cells, it should be appreciated that this two-step etching process can also be used in the manufacturing of passivated contact solar cells for the front junction and/or the rear junction for a bottom cell used in three-terminal (3T) tandem solar cell integration. Further, although the Si layer 102 of the solar cell 100 of the present embodiments comprises a textured passivated front side, in a variation, the solar cell 100 can comprise a non-textured (or planar) front side for better 3T tandem solar cell integration.

Further, although SiOₓ which has a moderate positive charge density has been used as the dielectric tunnel layer for the front side and/or the rear side in the previously described embodiments, in a variation, the dielectric tunnel layer 106, 126, 144, 150, 174, 180 can be formed by atomic layer deposited AlOₓ which has a high negative interface charge density.

It should be appreciated that the above described two-step etching process for treating a surface of the Si layer prior to passivated contact formation may be applied in the manufacturing of n-type front junction passivated contact solar cells using carrier selective alloyed (n⁺) silicon layers (e.g. the solar cell 100 of FIG. 1A) and the manufacturing of n-type rear junction passivated contact solar cells using carrier selective alloyed (p⁺) silicon layers (e.g. the solar cell 120 of FIG. 1B). In some embodiments, the two-step etching process can be performed on the front surface of the Si layer (e.g. if the emitter is formed at the back, or if passivated contacts are formed on both sides of the solar cell as shown in relation to FIGS. 1C and 1D).

In other embodiments, for the manufacturing of n-type rear junction both sides passivated contact solar cells (e.g. the solar cell 170 of FIG. 1D) using carrier selective alloyed (p⁺) silicon layers, the two-step etching process could be used directly if the starting wafer has planar surface on both sides. For this application, the unwanted p⁺ poly-Si formed on the front side of the solar cell could be etched away using the single component etching solution. Although p⁺ poly-Si could be etched with a highly concentrated (15-20 wt %) hot KOH solution or strong acidic etching solutions, such as HF+HNO₃, these solutions are aggressive and may damage the rear emitter protected by the mask through pinholes (in case of KOH) or may completely damage the mask itself (in case of an acidic etchant). The single component etching solution is slow and highly selective, hence it will only etch the unprotected poly-Si on the front. Alternatively, if the starting wafers have textured surface, the poly-Si on the front could be selectively etched using the single component solution without damaging the front textured surface morphology, which is not easily possible with other etching solutions. These provide further advantages/applications of the single component etching solution.

Other alternative embodiments include: (1) using a p-doped Si wafer or Si layer instead an n-doped Si wafer or Si layer, (2) where it is feasible to deploy single side deposition of boron-based dopants for forming the p⁺ emitter or phosphorous-based dopants for forming the n⁺ emitter in the solar cells, using only the second etching step of a single component etchant for a slow etch to achieve the desired roughness for passivated contact formation, (3) an acidic etching solution for use in the first etching step of the two-step etching process which includes nitric acid (HNO₃), acetic acid (CH₃COOH) or hydrofluoric (HF) acids singly or in any combination, (4) the first etching step of the two-step etching process using an acidic solution, an acidic mixture, an alkaline solution or an alkaline mixture, (5) an additional etching step prior to the two-step etching process for surface treating the Si layer prior to passivated contact formation, where the additional etching step may include etching using an alkaline solution, an alkaline mixture, an acidic solution or an acidic mixture, (6) the passivation layers 112, 114, 132, 134, 156, 158, 186, 188 comprising one or more of: AlOₓ, SiNₓ and/or SiOₓ, (7) a solar cell having an n⁺ emitter formed using phosphorus diffusion in a tube furnace at high temperature using POCl₃ as the dopant source, (8) where phosphorous-doped n⁺ emitter is formed, etching of the phosphorus wrap around on the non-emitter side (can be rear or front side) is done using a wet chemical etching process with an etchant that includes an acid (e.g. HF—HNO₃) or an alkaline (KOH) or a combination of both, (9) performing the first etching step and/or the second etching step of the two-step etching process of the surface treatment method 300 using a dry etching process, (10) where the Si layer is a crystalline Si layer or an amorphous Si layer, (11) where the Si layer is a monocrystalline Si layer or a polycrystalline Si layer, (12) the second etchant comprising a single component etchant, (13) the second etchant comprising ammonium hydroxide or tetramethylammonium hydroxide (TMAH), where ammonium hydroxide and TMAH are each a single component etchant, and (14) the step (i) of the method (e.g. the step 302) where etching a portion of the silicon layer may include a whole portion (i.e. an entire rear or front surface of the silicon layer), or a part of the rear or the front surface of the silicon layer.

Although only certain embodiments of the present invention have been described in detail, many variations are possible in accordance with the appended claims. For example, features described in relation to one embodiment may be incorporated into one or more other embodiments and vice versa.

1. A surface treatment method for forming a passivated contact of a solar cell, the solar cell comprising a silicon layer having a textured surface, the method comprising:
(i) etching a portion of the silicon layer using a first etchant to reduce surface protrusions of the textured surface and to provide an intermediate surface of the silicon layer; and
(ii) etching the intermediate surface of the silicon layer using a second etchant to form a treated surface of the silicon layer having a desired roughness for forming the passivated contact of the solar cell, the second etchant having a slower etching rate on silicon than that of the first etchant.

2. The method of claim 1, further comprising etching the silicon layer anisotropically to form the textured surface of the silicon layer.

3. The method of claim 1, wherein the second etchant is a single component etching solution.

4. The method of claim 3, wherein the second etchant includes sodium hypochlorite (NaOCl).

5. The method of claim 4, wherein the step (ii) of the method is performed at a temperature of 30° C. to 85° C. for a duration of 5 minutes to 15 minutes.

6. The method of claim 4, wherein a concentration of the NaOCl is in a range of 10% to 15% by weight.

7. The method of claim 1, wherein the desired roughness of the treated surface of the silicon layer is in a range of 0.2 μm to 0.5 μm.

8. The method of claim 1, wherein the silicon layer has a front side arranged to receive incident light and a rear side, the silicon layer is doped on both the front side and the rear side in a process for forming an emitter on the front side of the silicon layer, the step (i) of the method is adapted to etch away a doped layer of the silicon layer on the rear side for forming the passivated contact on the rear side of the silicon layer.

9. The method of claim 8, wherein the process includes doping the silicon layer using a boron dopant source, the first etchant includes a mixture of hydrofluoric (HF) and nitric acid (HNO₃).

10. The method of claim 8, further comprising depositing a masking layer on the front side of the silicon layer after the silicon layer is doped and prior to the step (i) of the method to protect a doped layer of the front side of the silicon layer.

11. The method of claim 1, wherein the first etchant includes a potassium hydroxide (KOH) solution or a mixture of hydrofluoric (HF) and nitric acid (HNO₃).

12. The method of claim 11, wherein the first etchant includes the KOH solution, the concentration of KOH is in a range of 2% to 20% by weight.

13. The method of claim 12, wherein the step (i) of the method is performed at a temperature of 30° C. to 85° C. for a duration of 15 seconds to 3 minutes.

14. The method of claim 11, wherein the first etchant includes the mixture of HF and HNO₃, the concentration of HF is in a range of 2% to 10% by weight and the concentration of HNO₃ is in a range of 25% to 45% by weight.

15. The method of claim 14, wherein the step (i) of the method is performed at a temperature of 18° C. to 30° C. for a duration of 30 seconds to 3 minutes.

16. The method of claim 1, wherein the method is performed using a batch wet chemical tool or an inline wet chemical tool.
